(19) United States
(12) Patent Application Publication
(10) Pub. No.: US 2024/0219824 A1
(43) Pub. Date: Jul. 4, 2024

(54) REFLECTIVE MASK FOR EXTREME ULTRAVIOLET LITHOGRAPHY AND A METHOD OF FABRICATING A SEMICONDUCTOR DEVICE USING THE SAME

(71) Applicant: SAMSUNG ELECTRONICS CO., LTD., SUWON-SI (KR)

(72) Inventors: AKIO MISAKA, Suwon-si (KR); NOYOUNG CHUNG, Suwon-si (KR); SEOKYUN JEONG, Suwon-si (KR)

(21) Appl. No.: 18/383,543

(22) Filed: Oct. 25, 2023

(30) Foreign Application Priority Data
Jan. 4, 2023 (KR) 10-2023-0001419

(51) Int. Cl. G03F 1/24; G03F 1/54; H01L 21/027; H01L 21/311; H01L 21/768

(52) U.S. Cl. CPC G03F 1/24; G03F 1/54; H01L 21/0274; H01L 21/31144; H01L 21/76817

(57) ABSTRACT

An extreme ultraviolet (EUV) reflective mask including: a mask substrate, a reflection layer on the mask substrate, and an absorption layer on the reflection layer, wherein the absorption layer includes a main pattern and non-diffraction patterns the main pattern, the non-diffraction patterns form a honeycomb shape, a pitch between the non-diffraction patterns is less than a diffraction limit, and the main pattern is isolated from the non-diffraction patterns.

### CROSS-REFERENCE TO RELATED APPLICATION

This U.S. non-provisional patent application claims priority under 35 U.S.C. § 119 to Korean Patent Application No. 10-2023-0001419, filed on Jan. 4, 2023, in the Korean Intellectual Property Office, the disclosure of which is incorporated by reference herein in its entirety.

### TECHNICAL FIELD

The present disclosure relates to a reflective mask for an extreme ultraviolet (EUV) lithography process and a method of fabricating a semiconductor device using the same.

### DISCUSSION OF RELATED ART

Semiconductor devices, valued for their small-size, multifunctionality, and low-cost, play a vital role in the electronics industry. Semiconductor devices are categorized into several types: memory devices for storing data, logic devices that process data, and hybrid devices that perform are range of functions.

With the advancement of the electronics industry, the demand for semiconductor devices with higher integration density continues to rise. Thus, a process margin in an exposure process, which is performed to define fine patterns, is being reduced. This reduction complicates the realization of semiconductor devices. Furthermore, as the electronics industry evolves, the need for high-performance semiconductor devices intensifies. As a result, numerous studies are being conducted to fulfill the growing demand for semiconductor devices with higher integration density and operation speed.

As the integration density of semiconductor devices increases, the demand for high resolution lithography systems also rises. In response to this, there is active development in extreme ultraviolet (EUV) exposure systems. These systems utilize EUV light, which has a shorter wavelength than deep ultraviolet (DUV) light, as their light source. For these EUV systems, a reflective mask is employed to reflect the EUV light.

### SUMMARY

An embodiment of the inventive concept provides a reflective mask for improving process reliability in an extreme ultraviolet (EUV) lithography process.

An embodiment of the inventive concept provides a method of fabricating a semiconductor device with improved reliability.

According to an embodiment of the inventive concept, there is provided an EUV reflective mask including: a mask substrate, a reflection layer on the mask substrate, and an absorption layer on the reflection layer, wherein the absorption layer includes a main pattern and non-diffraction patterns the main pattern, the non-diffraction patterns form a honeycomb shape, a pitch between the non-diffraction patterns is less than a diffraction limit, and the main pattern is isolated from the non-diffraction patterns.

According to an embodiment of the inventive concept, there is provided a method of fabricating a semiconductor device including: forming an etch target layer, a mask layer, and a photoresist layer sequentially stacked on a substrate; performing a printing process using an EUV reflective mask on the photoresist layer to form a photoresist pattern including a hole; and patterning the mask layer and the etch target layer using the photoresist pattern as an etch mask, wherein the EUV reflective mask comprises a main pattern and non-diffraction patterns, the non-diffraction patterns form a honeycomb shape, a pitch between the non-diffraction patterns is less than a diffraction limit, and the hole is printed from the main pattern.

According to an embodiment of the inventive concept, there is provided a method of fabricating a semiconductor device including: forming a front-end-of-line (FEOL) layer on a substrate, the FEOL layer comprising a plurality of transistors on the substrate; forming an interlayer insulating layer on the FEOL layer; forming a mask layer and a photoresist layer on the interlayer insulating layer; performing a printing process using an extreme ultraviolet (EUV) reflective mask on the photoresist layer to form a photoresist pattern including a hole; patterning the mask layer and the interlayer insulating layer using the photoresist pattern as an etch mask; and forming a via pattern or a contact pattern by filling the hole, which is in the interlayer insulating layer, with a metallic material, wherein the EUV reflective mask comprises an isolated pattern and non-diffraction patterns near the isolated pattern, a pitch between adjacent ones of the non-diffraction patterns is less than a diffraction limit, and the hole is printed from the isolated pattern.

### BRIEF DESCRIPTION OF THE DRAWINGS

FIG. 1 is a diagram schematically illustrating an extreme ultraviolet (EUV) exposure apparatus according to an embodiment of the inventive concept.

FIG. 2 is a plan view schematically illustrating a reflective mask, which is used in the EUV exposure apparatus of FIG. 1.

FIGS. 3A, 3B, and 3C are diagrams schematically illustrating the shape of an EUV light source according to an embodiment of the inventive concept.

FIG. 4A is an intensity profile of reflection light produced by dense patterns in a reflective mask.

FIG. 4B is an intensity profile of reflection light produced by an isolated pattern in a reflective mask.

FIG. 5 is an enlarged plan view illustrating a portion (e.g., M of FIG. 2) of a reflective mask according to a comparative example.

FIGS. 6A and 6B are diagrams illustrating an EUV lithography process using the reflective mask of FIG. 5 according to the comparative example.

FIG. 7 is an intensity profile of reflection light produced by the reflective mask of FIG. 5.

FIG. 8A is an enlarged plan view illustrating a portion (e.g., M of FIG. 2) of a reflective mask according to an embodiment of the inventive concept.

FIG. 8B is a sectional view taken along a line I-I′ of FIG. 8A.

FIGS. 9A and 9B are diagrams illustrating an EUV lithography process using the reflective mask of FIGS. 8A and 8B.

FIG. 10 is an intensity profile of reflection light produced by the reflective mask of FIGS. 8A and 8B.

FIG. 11 is a plan view illustrating a reflective mask according to an embodiment of the inventive concept.

FIGS. 12A, 12B, and 12C are aerial images measured by changing a pitch of non-diffraction patterns of FIG. 11.

FIG. 13 is an intensity profile of reflection light measured by changing a pitch of non-diffraction patterns of FIG. 11.

FIG. 14 is an enlarged plan view illustrating a portion (e.g., M of FIG. 2) of a reflective mask according to an embodiment of the inventive concept.

FIG. 15 is an intensity profile of reflection light produced by the reflective mask of FIG. 14.

FIG. 16 is a plan view illustrating a semiconductor device according to an embodiment of the inventive concept.

FIGS. 17A, 17B, 17C and 17D are sectional views taken along lines A-A′, B-B′, C-C′, and D-D′ of FIG. 16.

FIG. 18 is a plan view illustrating a reflective mask according to an embodiment of the inventive concept.

FIGS. 19A, 19B, 20A, and 20B are sectional views illustrating a method of fabricating a semiconductor device, according to an embodiment of the inventive concept.

### DETAILED DESCRIPTION OF THE EMBODIMENTS

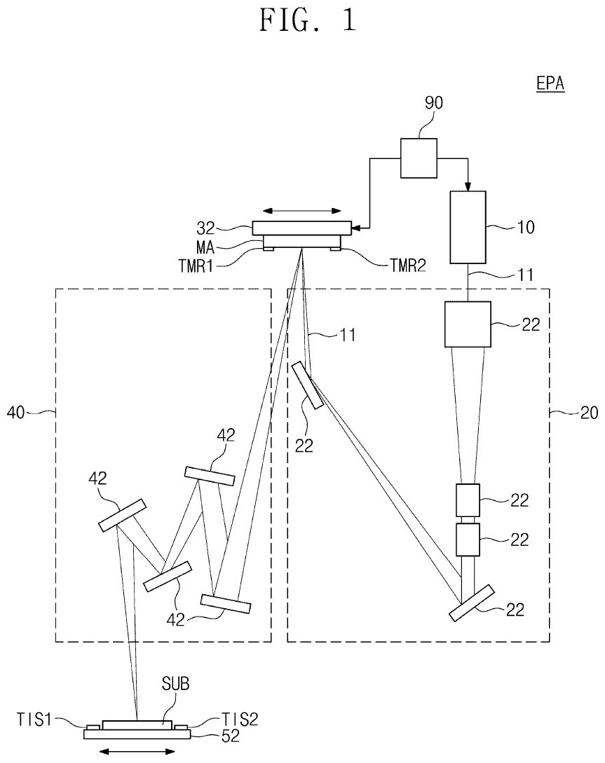

FIG. 1 is a diagram schematically illustrating an extreme ultraviolet (EUV) exposure apparatus according to an embodiment of the inventive concept. Referring to FIG. 1, an EUV exposure apparatus EPA may include an optical source unit 10, a condenser unit 20, a projection unit 40, and a control unit 90. The optical source unit 10 may be configured to generate EUV light (e.g., light having a wavelength of 4 nm to 124 nm). In an embodiment, the optical source unit 10 may be configured to generate EUV light (e.g., light having a wavelength of 13.5 nm). The optical source unit 10 may generate light having an energy of 6.21 eV to 124 eV, and, in particular, from 90 eV to 95 eV.

The optical source unit 10, during the generation of the EUV light, may undesirably generate deep ultraviolet (DUV) light (e.g., light having a wavelength from 100 nm to 300 nm). The condenser unit 20 may be configured to guide light 11, which is generated by the optical source unit 10, to a reflective mask MA, which is mounted on a mask stage 32 and is used to reflect the light 11.

The condenser unit 20 may include a condenser optics 22 (e.g., a lens or a mirror). The condenser optics 22 may be configured to collect the light 11 and reflect the light 11 to the reflective mask MA. The light 11 may be obliquely incident to the reflective mask MA through the condenser unit 20. The mask stage 32 may be configured to move the reflective mask MA in a scan direction of the reflective mask MA. The optical source unit 10 and the mask stage 32 may be controlled by the control unit 90.

The light 11, which is incident into the reflective mask MA, may be reflected by the reflective mask MA and may be obliquely incident to the projection unit 40. The projection unit 40 may be configured to project a mask pattern (e.g., an absorption pattern) of the reflective mask MA onto a substrate SUB placed on a substrate stage 52. For example, the substrate SUB may be a silicon wafer, on which an integrated circuit will be formed. The substrate SUB may be coated with a photoresist layer that is formed of a photoimageable material. The substrate stage 52 may move the substrate SUB to change an exposure region (or exposure position) of the substrate SUB.

The projection unit 40 may include a reflective projection optics 42 (e.g., a lens). The reflective projection optics 42 may project the mask pattern, which is formed on the reflective mask MA, onto the substrate SUB using the light 11, which is obliquely reflected by the reflective mask MA, in a reduction exposure manner (e.g., 4, 6, or 8 times).

In an embodiment, the substrate stage 52 may include a first alignment sensor TIS1 and a second alignment sensor TIS2. The first and second alignment sensors TIS1 and TIS2 may be respectively disposed near opposite sides of the substrate SUB. For example, the first and second alignment sensors TIS1 and TIS2 may be respectively disposed at first and second sides of the substrate SUB. The reflective mask MA may include a first alignment mark region TMR1 and a second alignment mark region TMR2, which are located at opposite sides of the reflective mask MA.

To effectively perform an exposure process from the reflective mask MA onto the substrate SUB using the EUV exposure apparatus EPA, the reflective mask MA should be accurately aligned with the substrate SUB. The first and second alignment mark regions TMR1 and TMR2 may include alignment marks for such an alignment. The first and second alignment sensors TIS1 and TIS2 may be used to inspect the first and second alignment mark regions TMR1 and TMR2 or obtain optical images of the first and second alignment mark regions TMR1 and TMR2.

The alignment inspection of the first alignment mark region TMR1 using the first alignment sensor TIS1 may include irradiating light, which is generated by the optical source unit 10, to the first alignment mark region TMR1 through the condenser unit 20 and irradiating or projecting light, which is reflected from the first alignment mark region TMR1, to the first alignment sensor TIS1 through the projection unit 40. The alignment inspection of the second alignment mark region TMR2 using the second alignment sensor TIS2 may include irradiating light, which is generated by the optical source unit 10, to the second alignment mark region TMR2 through the condenser unit 20 and irradiating or projecting light, which is reflected from the second alignment mark region TMR2, to the second alignment sensor TIS2 through the projection unit 40.

The alignment inspection of the first and second alignment mark regions TMR1 and TMR2 using the first and second alignment sensors TIS1 and TIS2 may be performed at the same time or sequentially. In an embodiment, each of the first and second alignment sensors TIS1 and TIS2 may include a transmission image sensor (TIS). The first and second alignment sensors TIS1 and TIS2 may be configured to sense light within an EUV wavelength range.

The alignment inspection of the first and second alignment mark regions TMR1 and TMR2 using the first and second alignment sensors TIS1 and TIS2 may be performed before the exposure process. This inspection process makes it possible to check whether or not the reflective mask MA and the substrate SUB are accurately aligned with each other. If a misalignment between the reflective mask MA and the substrate SUB exceeds a predetermined process tolerance, the mask stage 32 and/or the substrate stage 52 may be moved to reduce the misalignment, under the control of the control unit 90. If the alignment inspection using the first and second alignment sensors TIS1 and TIS2 indicates that the reflective mask MA and the substrate SUB are effectively aligned to each other, the exposure process may be performed without any additional movement of the stages 32 and/or 52.

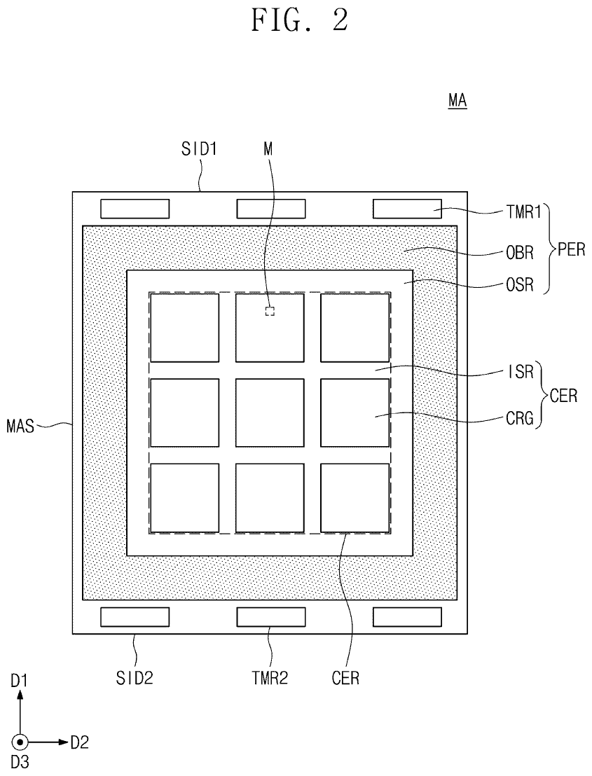

FIG. 2 is a plan view schematically illustrating a reflective mask, which is used in the EUV exposure apparatus of FIG. 1. Referring to FIG. 2, the reflective mask MA may include a center region CER and a peripheral region PER enclosing the center region CER.

The center region CER may include main regions CRG and an inner supplementary region ISR between the main regions CRG. For example, the main regions CRG may form rows and the inner supplementary region ISR may be located between the rows. The main regions CRG may correspond to respective chip regions (or dies) of the substrate SUB of FIG. 1. Each of the main regions CRG may be used to transcribe patterns, which constitute an integrated circuit, into the chip region of the substrate SUB of FIG. 1. The main regions CRG may be two-dimensionally arranged. The inner supplementary region ISR may be used to transcribe supplementary patterns into a scribe line region on the substrate SUB of FIG. 1.

The peripheral region PER may include an outer supplementary region OSR, an out-of-band region OBR, and the first and second alignment mark regions TMR1 and TMR2. The outer supplementary region OSR may enclose the center region CER. The outer supplementary region OSR may be used to transcribe supplementary patterns into the scribe line region on the substrate SUB of FIG. 1, similar to the inner supplementary region ISR.

The out-of-band region OBR may constitute a border of the reflective mask MA. The out-of-band region OBR may be a region treated by an optical density (OD) treatment process. The out-of-band region OBR may not reflect light, which is incident into the reflective mask MA, and may absorb or scatter the light completely. For example, the out-of-band region OBR may be configured to absorb EUV light and may scatter DUV light.

The center region CER and the outer supplementary region OSR of the reflective mask MA may be configured to reflect light incident to the reflective mask MA. In other words, patterns, which are formed in the center region CER and the outer supplementary region OSR, may be transcribed onto the substrate SUB of FIG. 1. Since light reflection does not occur in the out-of-band region OBR, patterns formed on the out-of-band region OBR may not be transcribed onto the substrate SUB.

A mask substrate MAS may include a first side SID1 and a second side SID2, which are opposite to each other in a first direction D1. The first alignment mark region TMR1 may be provided between the first side SID1 and the out-of-band region OBR. As shown in FIG. 2, three first alignment mark regions TMR1 are provided. The second alignment mark region TMR2 may be provided between the second side SID2 and the out-of-band region OBR. As shown in FIG. 2, three second alignment mark regions TMR2 are provided.

The first and second alignment mark regions TMR1 and TMR2 may be provided outside the out-of-band region OBR. Light reflected from the first and second alignment mark regions TMR1 and TMR2 may not be projected onto the substrate SUB and may be incident into the first and second alignment sensors TIS1 and TIS2 on the substrate stage 52.

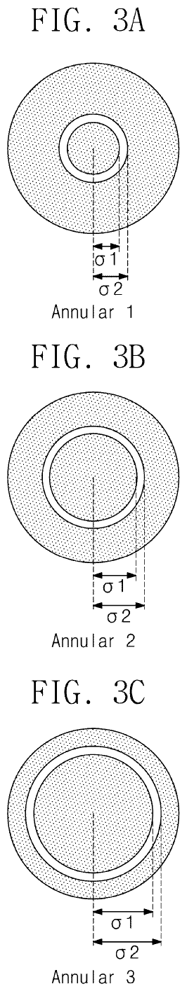

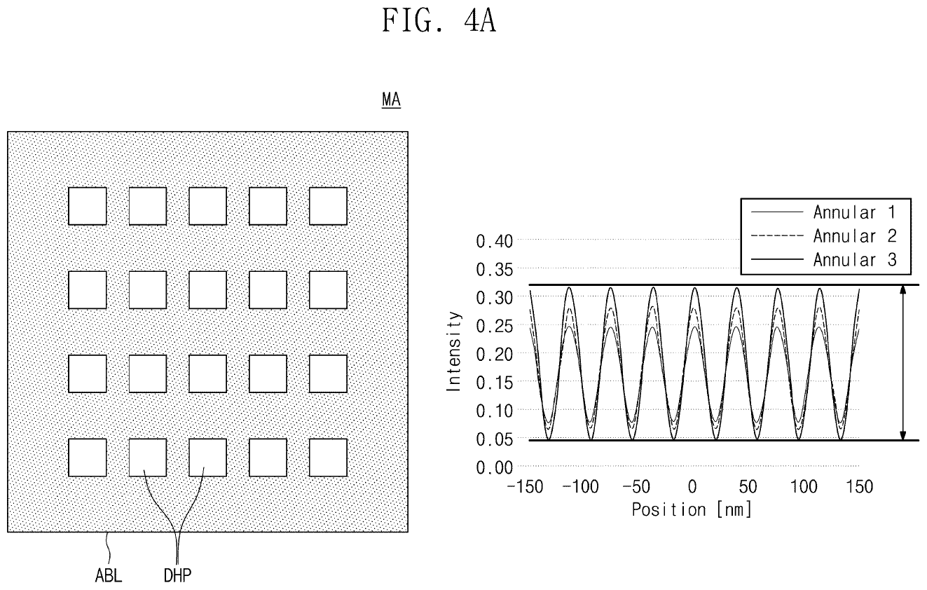

FIGS. 3A, 3B, and 3C are diagrams schematically illustrating the shape of an EUV light source according to an embodiment of the inventive concept. Referring to FIGS. 3A to 3C, in an embodiment, the EUV light source 10 of FIG. 1 may be an annular illumination.

The annular illumination may have an inner radius or sigma inner σ1 and an outer radius or sigma outer σ2. In an embodiment, for the first annular illumination (Annular 1) of FIG. 3A, the value of σ2/σ1 may be 0.4/0.3. For the second annular illumination (Annular 2) of FIG. 3B, the value of σ2/σ1 may be 0.6/0.5. For the third annular illumination (Annular 3) of FIG. 3C, the value of σ2/σ1 may be 0.8/0.7. The first annular illumination (Annular 1) may be a light source that is close to an on-axis illumination, and the third annular illumination (Annular 3) may be a light source that is close to an outer off-axis illumination.

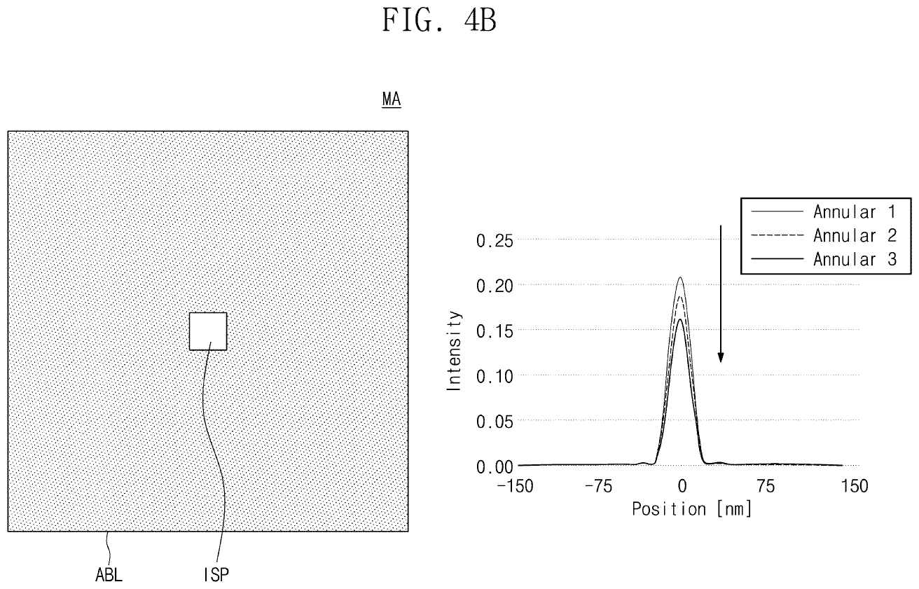

FIG. 4A is an intensity profile of reflection light produced by dense patterns in a reflective mask. Referring to FIG. 4A, dense patterns DHP may be provided in the reflective mask MA previously described with reference to FIGS. 1 and 2. The dense patterns DHP may be two-dimensionally arranged in an absorption layer ABL of the reflective mask MA to have a constant pitch.

FIG. 4A shows a result obtained by measuring an intensity of EUV light reflected from the dense patterns DHP. Intensities of the reflected EUV light were measured using the first, second, and third annular illuminations (Annular 1, Annular 2, and Annular 3) and were compared with each other. An intensity profile for the dense patterns DHP was superior when using the third annular illumination (Annular 3) compared to the first annular illumination (Annular 1). In other words, the intensity of the third annular illumination (Annular 3) was greater than the first annular illumination (Annular 1).

FIG. 4B is an intensity profile of reflection light produced by an isolated pattern in a reflective mask. As shown in FIG. 4B, an isolated pattern ISP may be provided in the reflective mask MA. Any pattern may not exist near or around the isolated pattern ISP. In other words, the isolated pattern ISP may have an island shape, in the absorption layer ABL.

FIG. 4B shows a result obtained by measuring an intensity of EUV light reflected from the isolated pattern ISP. Intensities of the reflected EUV light were measured using the first, second, and third annular illuminations (Annular 1, Annular 2, and Annular 3) and were compared with each other. An intensity profile for the isolated pattern ISP was superior when using the first annular illumination (Annular 1) compared to the third annular illumination (Annular 3). In other words, the intensity of the first annular illumination (Annular 1) was greater than the third annular illumination (Annular 3). This result is opposite that of the intensity profile of the dense patterns DHP previously described with reference to FIG. 4A. This shows that an outer off-axis illumination, such as the third annular illumination (Annular 3), is effective for the EUV lithography process on the dense patterns DHP but is ineffective for the EUV lithography process on the isolated pattern ISP.

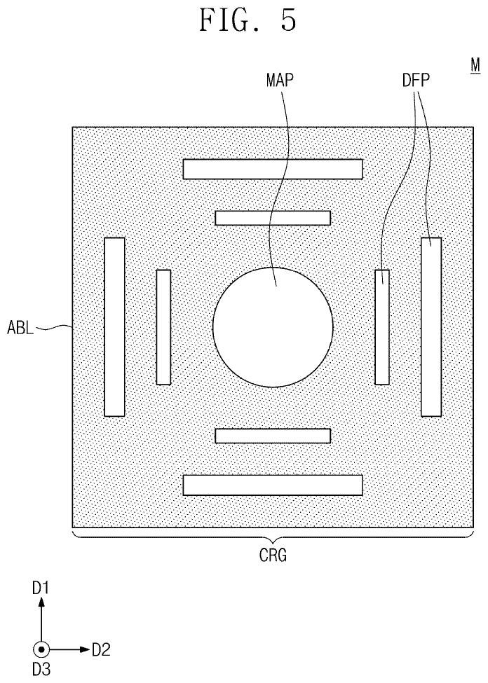

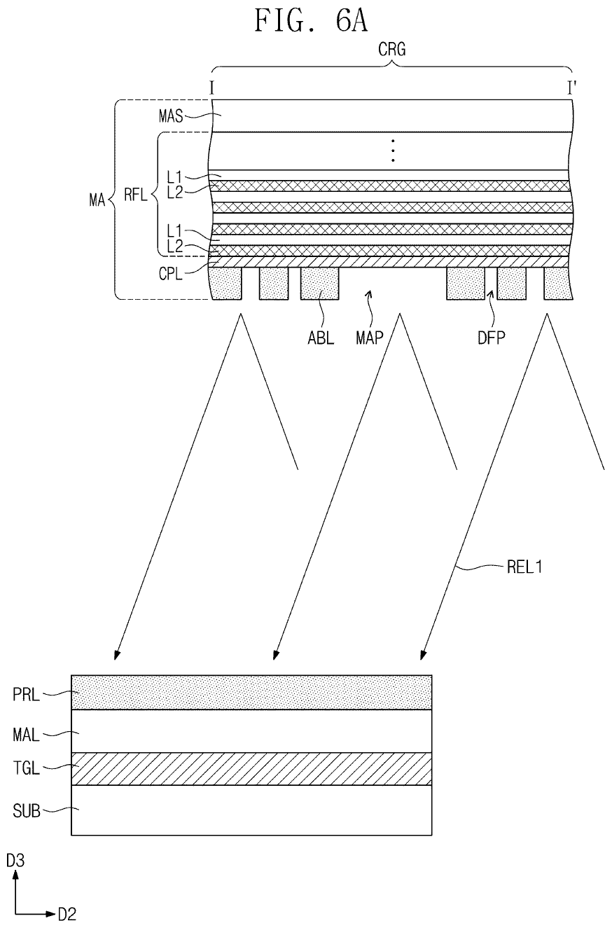

FIG. 5 is an enlarged plan view illustrating a portion (e.g., M of FIG. 2) of a reflective mask according to a comparative example. Referring to FIG. 5, a main pattern MAP may be provided in the main region CRG of the reflective mask MA. The main pattern MAP may define a circuit pattern, which will be formed on the substrate SUB. The main pattern MAP may be an isolated pattern described above.

In the comparative example, since an EUV lithography process with the outer off-axis illumination is ineffective for the isolated pattern or the main pattern MAP, diffraction patterns DFP may be provided around the main pattern MAP. The diffraction patterns DFP may be a sub-resolution assist feature (SRAF).

The SRAF, which is one of the technologies used in optical proximity correction (OPC), may permit correction of a critical dimension (e.g., CD) of a pattern, which is transcribed from the isolated pattern and may increase a depth of focus (DOF). The SRAF may improve reliability of an EUV lithography process, which is performed on an isolated pattern under the annular illumination described with reference to FIGS. 3A to 3C.

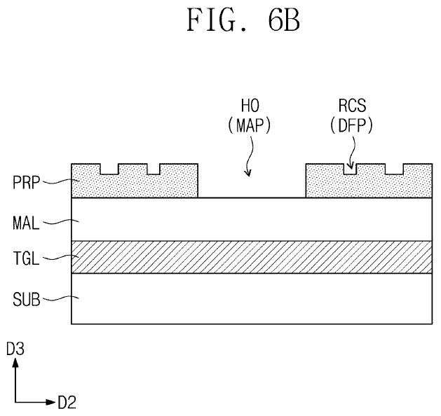

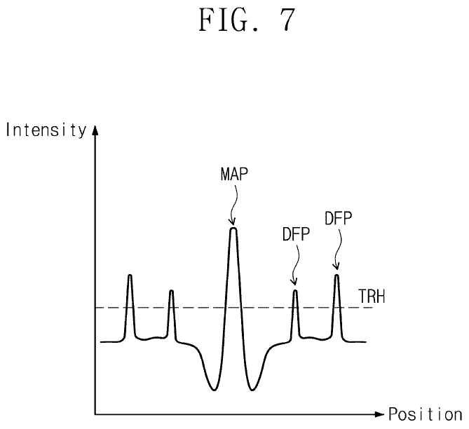

FIGS. 6A and 6B are diagrams illustrating an EUV lithography process using the reflective mask of FIG. 5 according to the comparative example.

Referring to FIG. 6A, the reflective mask MA may include a mask or reticle substrate MAS, a reflection layer RFL, a capping layer CPL, and the absorption layer ABL. The mask substrate MAS may be a glass or quartz substrate. The reflection layer RFL may be disposed on the mask substrate MAS. The reflection layer RFL may reflect light incident thereto. In an embodiment, the reflection layer RFL may have a multi-layered structure, in which first layers L1 and second layers L2 are alternately stacked to form 30 to 60 layers. For example, the first layer L1 may include silicon (Si) and/or a silicon compound. The second layer L2 may include molybdenum (Mo) and/or a molybdenum compound.

The capping layer CPL may be provided on the reflection layer RFL to protect the reflection layer RFL. For example, the capping layer CPL may include ruthenium (Ru) or ruthenium oxide. In an embodiment, the capping layer CPL may be omitted.

The absorption layer ABL may be provided on the capping layer CPL. The absorption layer ABL may include an inorganic material or a metallic material. The absorption layer ABL may be formed of or include at least one of ruthenium alloys, tantalum alloys, tantalum-based compounds (e.g., TaN, TaBN, or TaBON), or combinations thereof. For example, the ruthenium alloys may contain ruthenium (Ru) and at least one selected from the group consisting of chromium (Cr), nickel (Ni), and cobalt (Co). The tantalum alloys may contain tantalum (Ta) and at least one selected from the group consisting of chromium (Cr), nickel (Ni), and cobalt (Co). In an embodiment, any optically-opaque inorganic material or any optically-opaque metallic material (e.g., Cr, CrO, Ni, Cu, Mo, Al, Ti, W, or Ru) may be used as a material of the absorption layer ABL. The absorption layer ABL may be exposed to the outside of the reflective mask MA.

The reflective mask MA may be an EUV binary mask or an EUV phase shift mask (EUV PSM). By using the EUV PSM in an EUV lithography process, it may be possible to realize a high resolution, compared with the EUV binary mask. The absorption layer ABL of the EUV PSM may have higher EUV reflectance than the absorption layer ABL of the EUV binary mask. For example, the absorption layer ABL of the EUV binary mask may have EUV reflectance of about 3%, but the absorption layer ABL of the EUV PSM may have EUV reflectance of 10% or higher. Due to the high reflectance of the absorption layer ABL of the EUV PSM, it may be possible to improve patterning resolution in the EUV lithography process and performance in a subsequent patterning process.

However, the high reflectance of the absorption layer ABL of the EUV PSM may have a negative influence on an intensity profile of the isolated pattern of FIG. 4B described above. In other words, when the EUV PSM is used, the intensity profile of the isolated pattern may be worsen compared with that of the EUV binary mask.

The main and diffraction patterns MAP and DFP of FIG. 5 may be provided in the absorption layer ABL of the reflective mask MA. The main pattern MAP may be a hole-shaped pattern exposing the reflection layer RFL. For example, the main pattern MAP may have a circular shape and be surrounded by the diffraction pattern DFP. The diffraction pattern DFP may be a trench-shaped pattern exposing the reflection layer RFL.

The substrate SUB may be provided on the substrate stage described with reference to FIG. 1. An etch target layer TGL, a mask layer MAL, and a photoresist layer PRL may be provided on the substrate SUB. The mask layer MAL may include a plurality of mask layers, which are sequentially stacked. Each of the mask layers may include an amorphous carbon layer, a silicon layer, a silicon oxide layer, a silicon nitride layer, a silicon oxynitride layer, or a metal layer.

The photoresist layer PRL may include a resist material that can be exposed by EUV light and can be developed. In an embodiment, the photoresist layer PRL may include an organic photoresist layer containing an organic polymer (e.g., polyhydroxystyrene). The organic photoresist layer may further include a photosensitive compound which can be reacted with the EUV light. The organic photoresist layer may further contain a material having high EUV absorptivity (e.g., organometallic materials, iodine-containing materials, or fluorine-containing materials). In another embodiment, the photoresist layer PRL may include an inorganic photoresist layer containing an inorganic material (e.g., tin oxide).

In the conventional technology, a multi-patterning technique (MPT), in which two or more photomasks are used, is employed to form patterns with a fine pitch on a wafer. By contrast, in the case where the EUV lithography process according to an embodiment of the inventive concept is used, it is possible to form the fine patterns, even when just one photomask (e.g., just one reflective mask MA) is used for the lithography process.

The annular illumination described with reference to FIGS. 3A to 3C may be used to send the EUV light to the reflective mask MA. The EUV light may be reflected by the reflection layer RFL, which is exposed by the main pattern MAP and the diffraction pattern DFP, and as a result, a first reflection light REL1 may be generated. The first reflection light REL1 may pass through the projection unit 40 of FIG. 1 and may be incident into the photoresist layer PRL.

Referring to FIG. 6B, the exposed photoresist layer PRL may be developed to form a photoresist pattern PRP on the mask layer MAL. The photoresist pattern PRP may include a hole HO corresponding to the main pattern MAP. The photoresist pattern PRP may further include a recess RCS corresponding to the diffraction pattern DFP. The hole HO may expose the surface of the mask layer MAL. The recess RCS may not reach the surface of the mask layer MAL.

In an embodiment, the diffraction pattern DFP may not be printed in the photoresist pattern PRP, and in this case, it is possible to perform a EUV lithography process in a defect-free manner. For example, the recess RCS, which is formed in an upper portion of the photoresist pattern PRP, may serve as a source causing a process defect in the EUV lithography process. The recess RCS may be formed by constructive interference of the first reflection light REL1 by the diffraction pattern DFP of the reflective mask MA.

FIG. 7 is an intensity profile of reflection light produced by the reflective mask of FIG. 5. For example, FIG. 7 shows an intensity profile of the first reflection light REL1 described with reference to FIG. 6A. Hereinafter, a threshold value TRH of the reflection light may refer to the minimum intensity of light that is required to effectively perform a printing (or developing) process on the photoresist layer PRL. FIG. 7 shows that a reflection light, which has an intensity higher than the threshold value TRH, may include light reflected by not only the main pattern MAP but also the diffraction pattern DFP. For example, the amount of reflection light reflected by the diffraction pattern DFP exceeds the threshold value TRH at least two times as shown in FIG. 7.

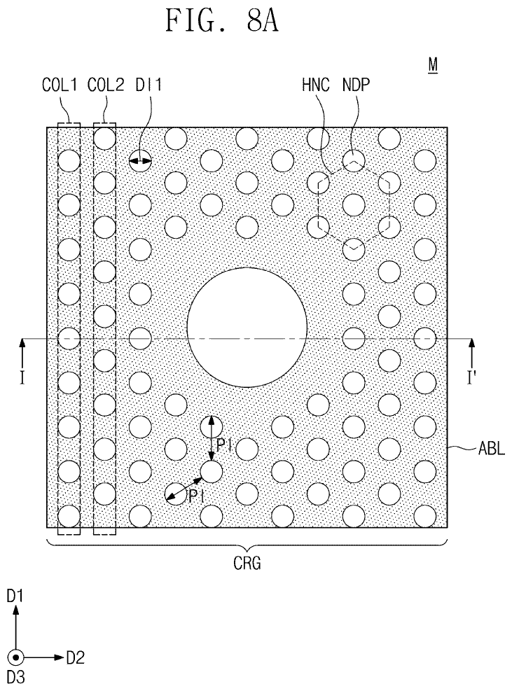

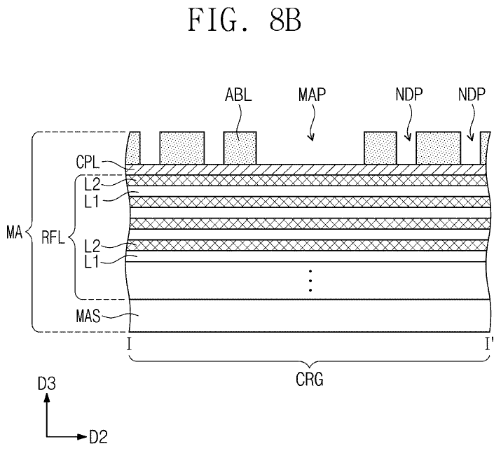

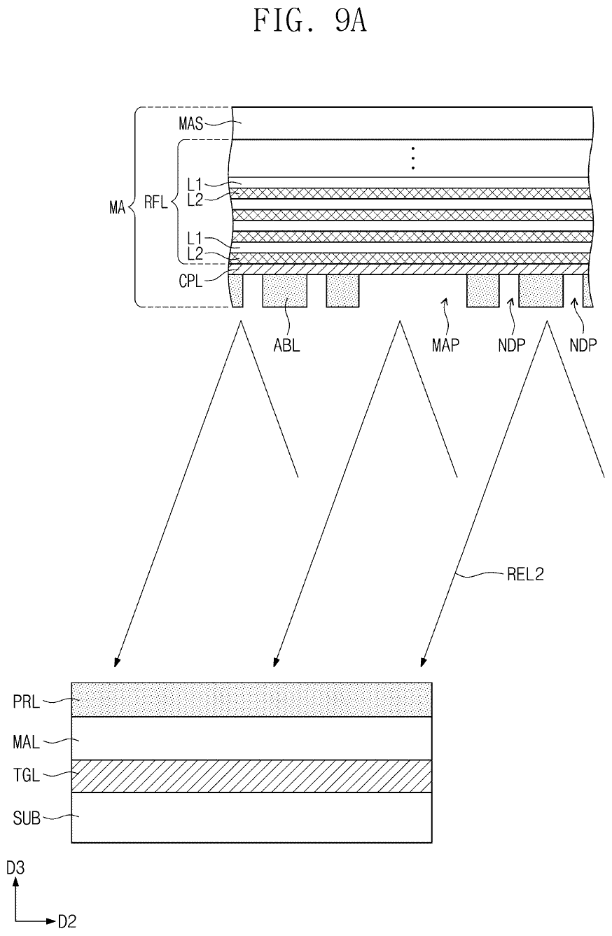

FIG. 8A is an enlarged plan view illustrating a portion (e.g., M of FIG. 2) of a reflective mask according to an embodiment of the inventive concept. FIG. 8B is a sectional view taken along a line I-I′ of FIG. 8A.

Referring to FIGS. 8A and 8B, the reflective mask MA may include the main pattern MAP and non-diffraction patterns NDP, which are provided around the main pattern MAP. Each of the non-diffraction patterns NDP may have a circular shape, but the inventive concept is not limited to this example. For example, each of the non-diffraction patterns NDP may have various shapes (e.g., triangular, rectangular, or other polygonal shapes).

A pitch PI of the non-diffraction patterns NDP adjacent to each other may be maintained to be constant. For example, the non-diffraction patterns NDP may be arranged in a honeycomb shape HNC.

The non-diffraction patterns NDP, which are arranged in the first direction D1, may constitute a first column COL1 and a second column COL2. The first column COL1 and the second column COL2 may be adjacent to each other in a second direction D2. The second column COL2 may be offset from the first column COL1 in the first direction D1. The second column COL2 may be offset from the first column COL1 by a half pitch (e.g., PI/2). Since the first and second columns COL1 and COL2 are alternately arranged in the second direction D2, the non-diffraction patterns NDP may have a honeycomb shape HNC.

The non-diffraction pattern NDP, which is closest to the main pattern MAP, may be spaced apart from the main pattern MAP by a minimum CD. The minimum CD may be the smallest size or width achievable by the EUV lithography process.

In an embodiment, the reflective mask MA may include the mask or reticle substrate MAS, the reflection layer RFL, the capping layer CPL, and the absorption layer ABL. The mask substrate MAS, the reflection layer RFL, the capping layer CPL, and the absorption layer ABL may be configured to have substantially the same features as those in the previous embodiment described with reference to FIG. 6A. In an embodiment, the reflective mask MA may be an EUV PSM or an EUV binary mask.

The main pattern MAP and the non-diffraction patterns NDP may be provided in the absorption layer ABL. The main pattern MAP and the non-diffraction patterns NDP may have a hole shape exposing the reflection layer RFL. For example, the main pattern MAP and the non-diffraction patterns NDP may expose a second layer L2 of the reflection layer RFL. The non-diffraction patterns NDP may have the same diameter (e.g., a first diameter DI1).

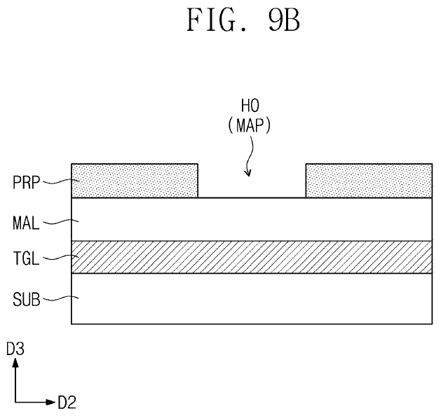

FIGS. 9A and 9B are diagrams illustrating an EUV lithography process using the reflective mask of FIGS. 8A and 8B.

Referring to FIG. 9A, the annular illumination described with reference to FIGS. 3A to 3C may be used to send the EUV light to the reflective mask MA. In an embodiment, the annular illumination in the present embodiment may be the third annular illumination (Annular 3) of FIG. 3C. The EUV light may be reflected by the reflection layer RFL, which is exposed by the main pattern MAP and the non-diffraction patterns NDP, and as a result, a second reflection light REL2 may be generated. The second reflection light REL2 may pass through the projection unit 40 of FIG. 1 and may be incident into the photoresist layer PRL.

Referring to FIG. 9B, the exposed photoresist layer PRL may be developed to form the photoresist pattern PRP on the mask layer MAL. The photoresist pattern PRP may include the hole HO corresponding to the main pattern MAP. The recess RCS may be omitted from the photoresist pattern PRP in the present embodiment, unlike the photoresist pattern PRP of FIG. 6B. In other words, the photoresist pattern PRP may include only the hole HO and may have a flat top surface. For example, due to the non-diffraction patterns NDP no recess may be formed in the photoresist pattern PRP, unlike that shown in FIG. 6B.

As described above, the recess RCS, which is formed in an upper portion of the photoresist pattern PRP, may lead to a process defect in an EUV lithography process. However, in the case where the EUV lithography process is performed using the reflective mask MA according to an embodiment of the inventive concept, the recess RCS may not be formed in the upper portion of the photoresist pattern PRP. As a result, it is possible to improve reliability in the EUV lithography process according to an embodiment of the inventive concept.

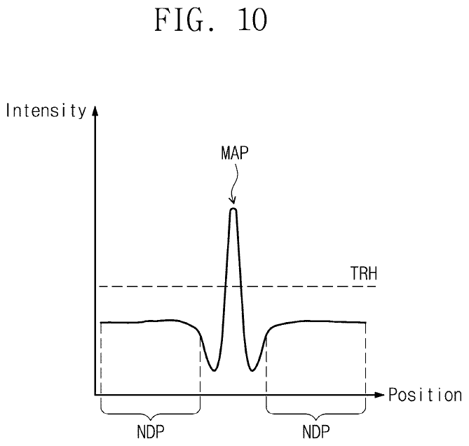

FIG. 10 is an intensity profile of reflection light produced by the reflective mask of FIGS. 8A and 8B. FIG. 10 shows an intensity profile of the second reflection light REL2 described with reference to FIG. 9A. Only the reflection light, which is reflected by the main pattern MAP, may have an intensity greater than the threshold value TRH. The non-diffraction patterns NDP may not cause the diffraction of the reflection light, and thus, an intensity profile of the reflection light, which is reflected by the non-diffraction patterns NDP, may be flat. An intensity of the reflection light by the non-diffraction patterns NDP may be controlled to a value less than the threshold value TRH. Since the intensity of the reflection light by the non-diffraction patterns NDP is less than the threshold value TRH, recesses may not be formed in the photoresist layer PRL as shown in FIG. 9A.

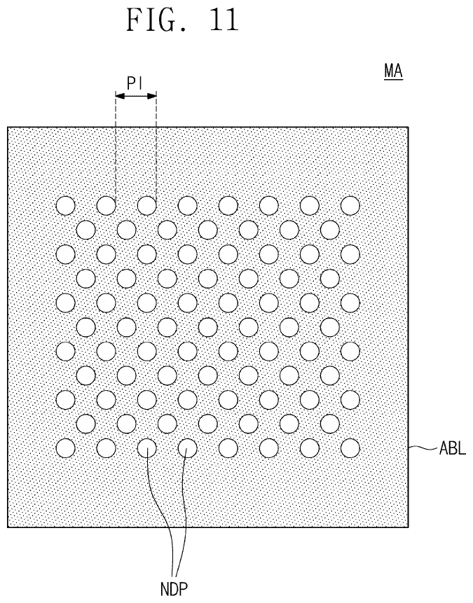

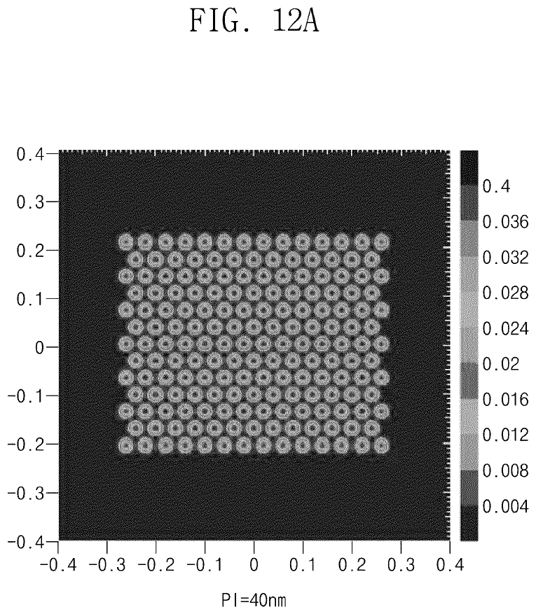

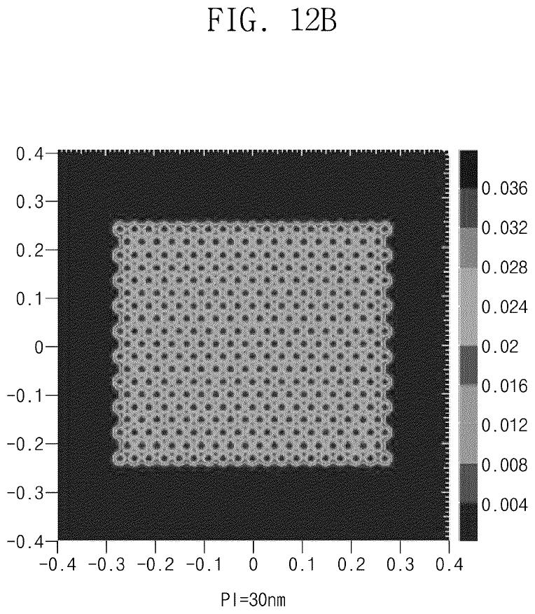

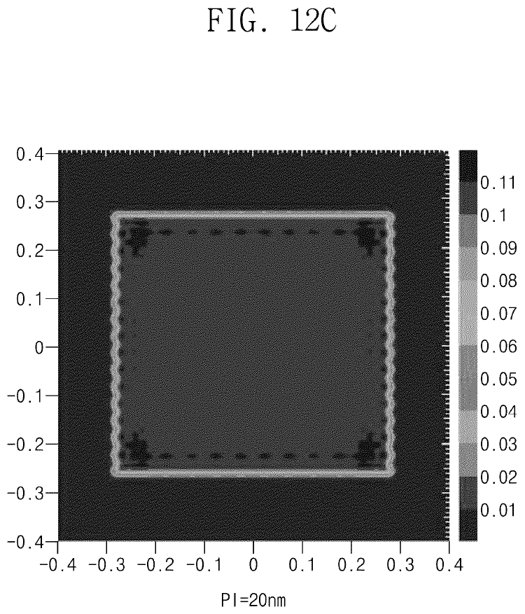

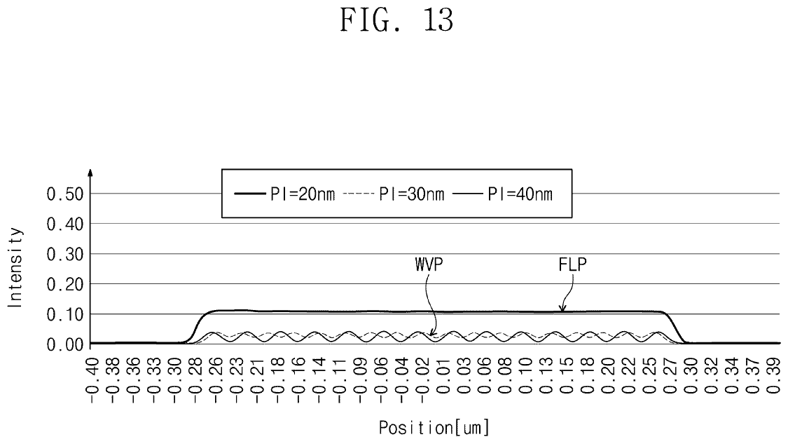

FIG. 11 is a plan view illustrating a reflective mask according to an embodiment of the inventive concept. FIGS. 12A, 12B, and 12C are aerial images measured by changing a pitch of non-diffraction patterns of FIG. 11. FIG. 13 is an intensity profile of reflection light measured by changing a pitch of non-diffraction patterns of FIG. 11.

Referring to FIG. 11, the reflective mask MA, which includes only the non-diffraction patterns NDP previously described with reference to FIGS. 8A and 8B, may be provided. The non-diffraction patterns NDP may be arranged at a constant pitch PI in a honeycomb shape. Aerial images and intensity profiles of EUV reflection light were obtained while varying the pitch PI between the non-diffraction patterns NDP at 40 nm, 30 nm, and 20 nm.

In the present specification, a term (e.g., “nanometer (nm)”) associated with a pattern size of the reflective mask MA may mean a size of a pattern that will be actually formed on the substrate SUB (e.g., a wafer). An actual pattern size in the reflective mask MA may vary depending on a magnification power (e.g., 4×, 6×, or 8×) of the projection unit 40. For example, if the magnification power is 4× and the pitch PI between the non-diffraction patterns NDP is 40 nm, the pitch PI between the non-diffraction patterns NDP, which are actually formed in the reflective mask MA, may be 160 nm.

FIGS. 12A, 12B, and 13 show that if the pitch PI of the non-diffraction patterns NDP has a relatively large value, an intensity distribution has a shape closely corresponding to the non-diffraction patterns NDP. FIG. 13 shows that the intensity profile has a wavy profile WVP for the pitches of FIGS. 12A and 12B. This means that if the pitch PI between the non-diffraction patterns NDP is larger than 30 nm, the non-diffraction patterns NDP may be printed in the photoresist layer.

By contrast, FIGS. 12C and 13 show that if the pitch PI of the non-diffraction patterns NDP has a relatively small value (e.g., 20 nm), a uniform intensity distribution can be realized. FIG. 13 shows that the intensity profile has a flat profile FLP for the pitch of FIG. 12. This means that if the pitch PI between the non-diffraction patterns NDP is 20 nm, the non-diffraction patterns NDP may not be printed in the photoresist layer.

A suitable value for the pitch PI of the non-diffraction patterns NDP may be determined, based on the afore-described method. In an embodiment, the suitable value for the pitch PI of the non-diffraction patterns NDP may be determined to obtain the intensity distribution shown in FIG. 12C. In an embodiment, the pitch PI of the non-diffraction patterns NDP may be determined to be less than a diffraction limit. The diffraction limit may be given by the following formula 1.

$$\frac{λ}{NA \times ( 1 + σ2 )} \qquad [ Formula 1 ]$$

where λ is a wavelength of the EUV light and may be 13.5 nm, NA is a numerical aperture of the projection unit 40 and may be 0.33 or 0.55, and σ2 is the outer radius or sigma outer of the annular illumination of FIGS. 3A to 3C. For example, for the third annular illumination (Annular 3) of FIG. 3C, 62 may be 0.8. If the values of NA and σ2 are 0.33 and 0.8, respectively, the above formula gives the diffraction limit of 22.7 nm. In this case, the pitch PI of the non-diffraction patterns NDP may be determined as a value that is less than 22.7 nm. If the values of NA and σ2 are 0.55 and 0.8, respectively, the formula gives the diffraction limit of 13.6 nm. In this case, the pitch PI of the non-diffraction patterns NDP may be determined as a value that is less than 13.6 nm.

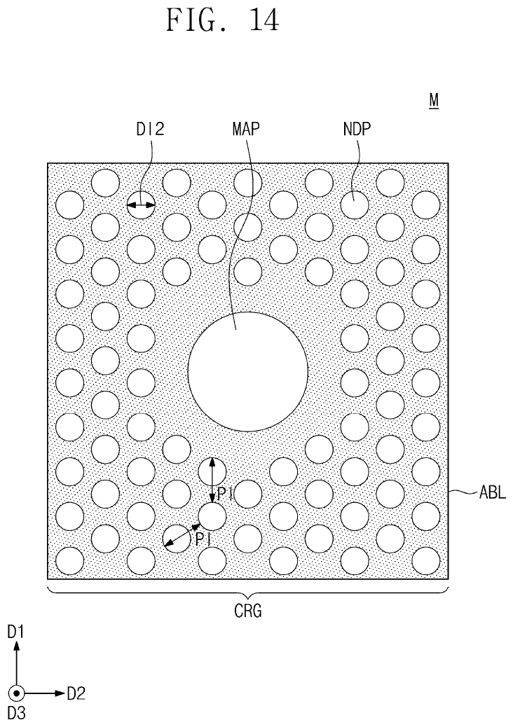

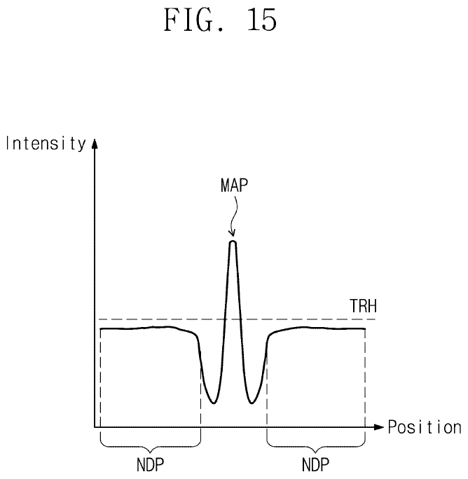

FIG. 14 is an enlarged plan view illustrating a portion (e.g., M of FIG. 2) of a reflective mask according to an embodiment of the inventive concept. FIG. 15 is an intensity profile of reflection light produced by the reflective mask of FIG. 14.

Referring to FIG. 14, the pitch PI of the non-diffraction patterns NDP may be equal to the pitch PI of the non-diffraction patterns NDP of FIG. 8A. In other words, the pitch PI of the non-diffraction patterns NDP may be determined to be less than the diffraction limit described above. Furthermore, each of the non-diffraction patterns NDP may have a second diameter DI2. The second diameter DI2 may be larger than the first diameter DI1 of FIG. 8A.

Referring to FIG. 15, in the case where the diameter of the non-diffraction pattern NDP is increased, an intensity of reflection light by the non-diffraction patterns NDP may be increased. If the intensity of the reflection light by the non-diffraction patterns NDP is controlled to be less than the threshold value TRH, the non-diffraction patterns NDP may not be printed in the photoresist layer, even when the intensity of the reflection light by the non-diffraction patterns NDP is increased. In other words, the non-diffraction patterns NDP may not form recesses in the photoresist layer. In an embodiment, the diameter of the non-diffraction pattern NDP may be controlled to adjust the intensity of the reflection light by the non-diffraction patterns NDP to a desired value, and in this case, it is possible to maximize the SRAF effect.

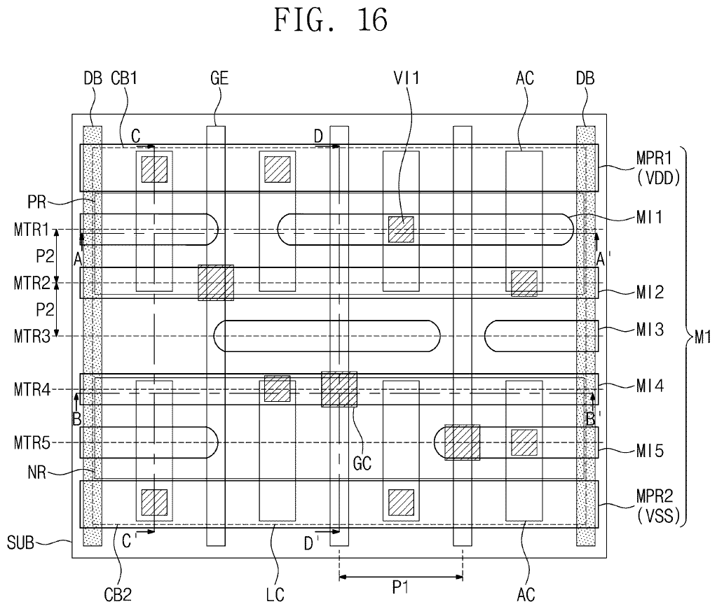

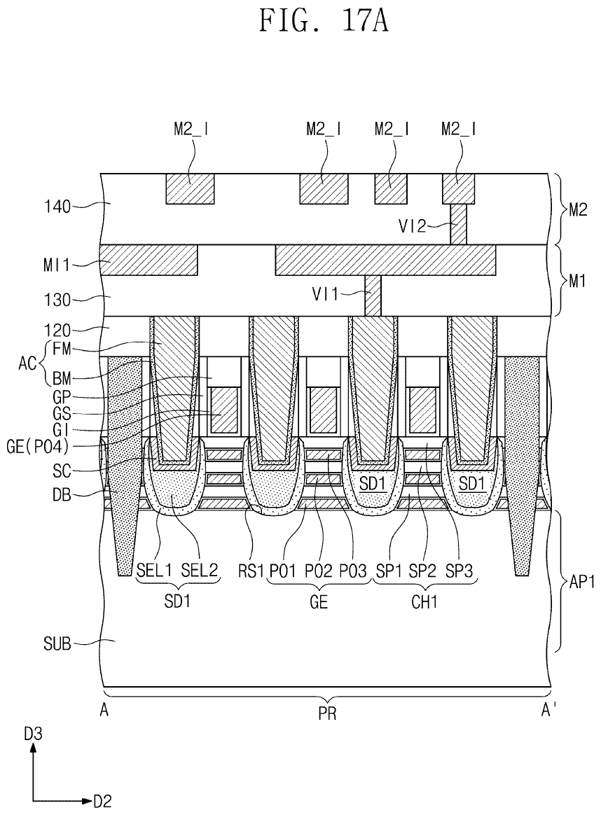

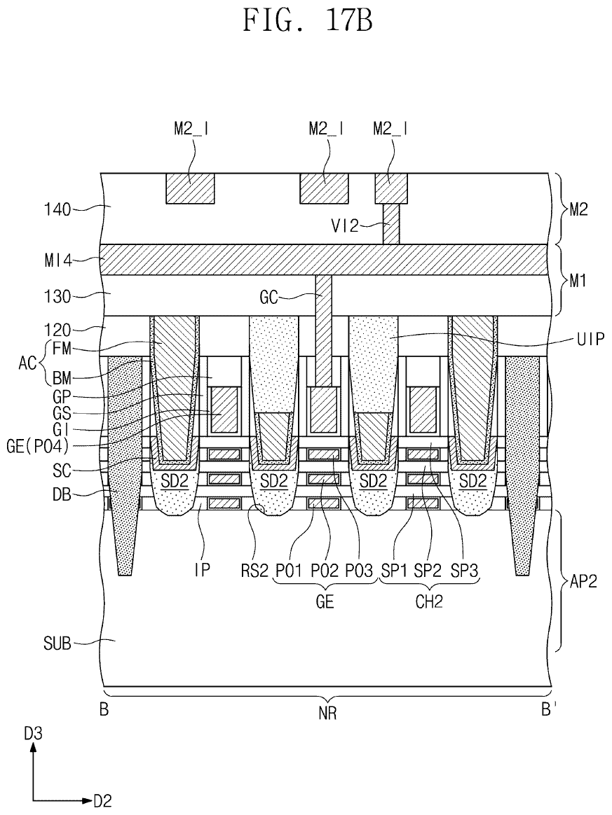

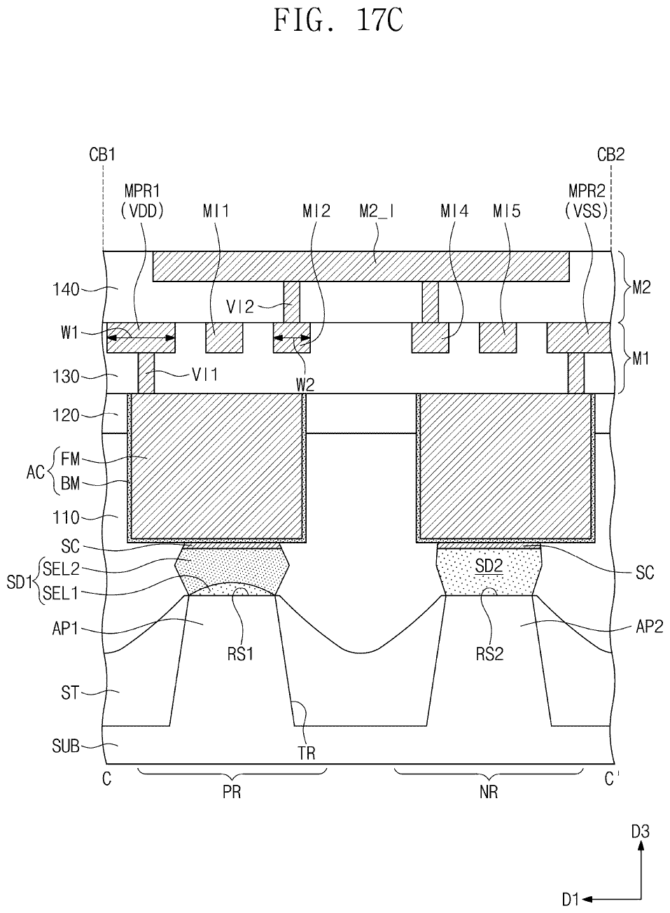

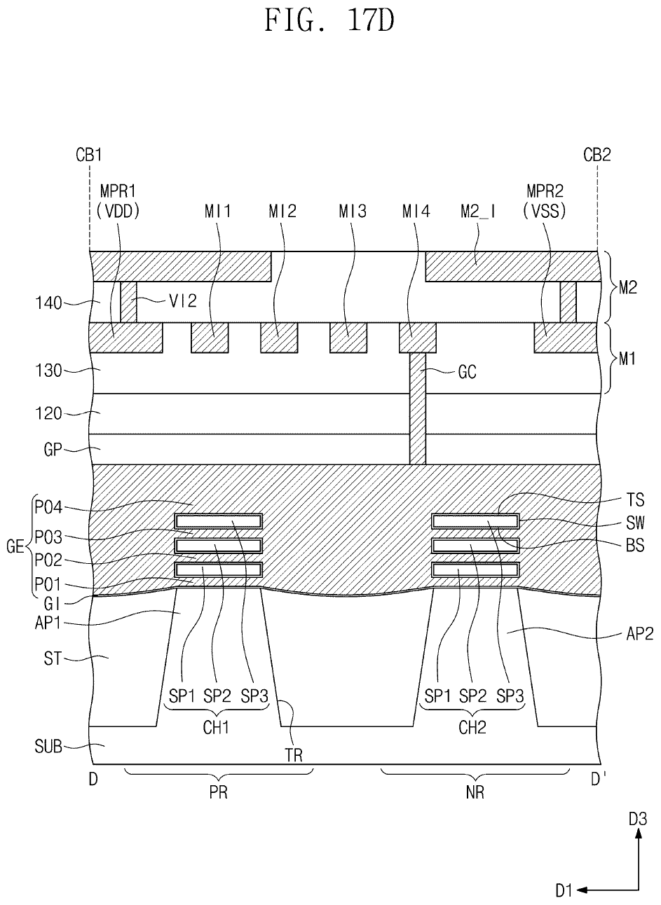

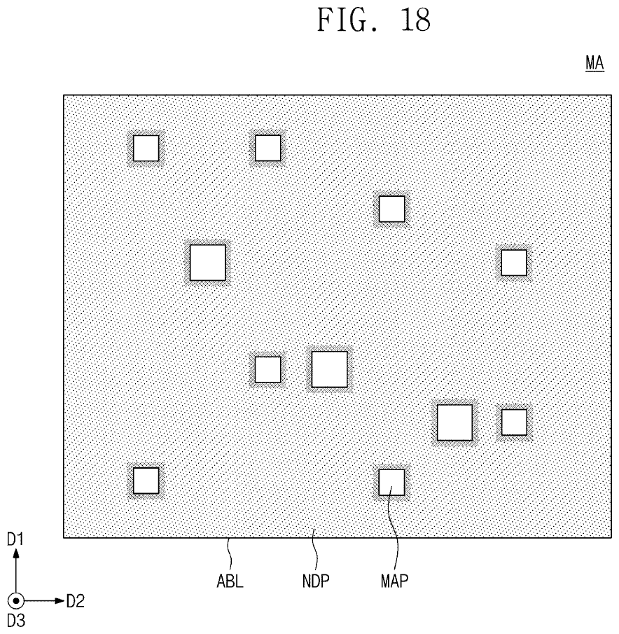

FIG. 16 is a plan view illustrating a semiconductor device according to an embodiment of the inventive concept. FIGS. 17A to 17D are sectional views taken along lines A-A′, B-B′, C-C′, and D-D′ of FIG. 16.

Referring to FIGS. 16 and 17A to 17D, a logic cell LC may be provided on the substrate SUB. The substrate SUB may be a semiconductor substrate, which is made of silicon, germanium, or silicon-germanium, or a substrate, which is made of a compound semiconductor material. As an example, the substrate SUB may be a silicon wafer.

Logic transistors constituting a logic circuit may be disposed on the logic cell LC. The logic cell LC may include a PMOSFET region PR and an NMOSFET region NR. The PMOSFET and NMOSFET regions PR and NR may be spaced apart from each other in the first direction D1.

A first active pattern AP1 and a second active pattern AP2 may be defined by a trench TR, which is formed in an upper portion of the substrate SUB. The first and second active patterns AP1 and AP2 may be provided on the PMOSFET and NMOSFET regions PR and NR, respectively. The first and second active patterns AP1 and AP2 may be extended in a second direction D2. The first and second active patterns AP1 and AP2 may be vertically-protruding portions of the substrate SUB.

A device isolation layer ST may be provided to fill the trench TR. The device isolation layer ST may include a silicon oxide layer. The device isolation layer ST may not cover first and second channel patterns CH1 and CH2 to be described below.

The first channel pattern CH1 may be provided on the first active pattern AP1. The second channel pattern CH2 may be provided on the second active pattern AP2. Each of the first and second channel patterns CH1 and CH2 may include a first semiconductor pattern SP1, a second semiconductor pattern SP2, and a third semiconductor pattern SP3, which are sequentially stacked. The first to third semiconductor patterns SP1, SP2, and SP3 may be spaced apart from each other in a vertical direction (e.g., a third direction D3).

Each of the first to third semiconductor patterns SP1, SP2, and SP3 may be formed of or include at least one of silicon (Si), germanium (Ge), or silicon-germanium (SiGe). In an embodiment, each of the first to third semiconductor patterns SP1, SP2, and SP3 may be formed of or include crystalline silicon. The first to third semiconductor patterns SP1, SP2, and SP3 may be nanosheets, which are stacked.

A plurality of first source/drain patterns SD1 may be provided on the first active pattern AP1. A plurality of first recesses RS1 may be formed in an upper portion of the first active pattern AP1. The first source/drain patterns SD1 may be provided in the first recesses RS1, respectively. The first source/drain patterns SD1 may be impurity regions of a first conductivity type (e.g., p-type). The first channel pattern CH1 may be interposed between each pair of the first source/drain patterns SD1. In other words, each pair of the first source/drain patterns SD1 may be connected to each other by the stacked first to third semiconductor patterns SP1, SP2, and SP3.

A plurality of second source/drain patterns SD2 may be provided on the second active pattern AP2. A plurality of second recesses RS2 may be formed in an upper portion of the second active pattern AP2. The second source/drain patterns SD2 may be provided in the second recesses RS2, respectively. The second source/drain patterns SD2 may be impurity regions of a second conductivity type (e.g., n-type). The second channel pattern CH2 may be interposed between each pair of the second source/drain patterns SD2. In other words, the pair of the second source/drain patterns SD2 may be connected to each other by the stacked first to third semiconductor patterns SP1, SP2, and SP3.

The first and second source/drain patterns SD1 and SD2 may be epitaxial patterns, which are formed by a selective epitaxial growth (SEG) process. As an example, each of the first and second source/drain patterns SD1 and SD2 may have a top surface that is located at substantially the same level as a top surface of the third semiconductor pattern SP3. However, in an embodiment, the top surface of each of the first and second source/drain patterns SD1 and SD2 may be higher than the top surface of the third semiconductor pattern SP3.

The first source/drain patterns SD1 may be formed of or include a semiconductor material (e.g., SiGe) whose lattice constant is larger than a lattice constant of the semiconductor material of the substrate SUB. Accordingly, each pair of the first source/drain patterns SD1 may exert a compressive stress on the first channel pattern CH1 therebetween. In an embodiment, the second source/drain patterns SD2 may be formed of or include the same semiconductor material (e.g., Si) as the substrate SUB.

Each of the first source/drain patterns SD1 may include a first semiconductor layer SEL1 and a second semiconductor layer SEL2 on the first semiconductor layer SEL1. A sectional shape of the first source/drain pattern SD1 taken in the second direction D2 will be described with reference to FIG. 17A.

The first semiconductor layer SEL1 may be provided to cover an inner surface of the first recess RS1. In other words, the first semiconductor layer SEL1 may be in contact with the substrate SUB. The first semiconductor layer SEL1 may have a decreasing thickness in an upward direction. For example, the thickness of the first semiconductor layer SEL1, which is measured in the third direction D3 at the bottom level of the first recess RS1, may be larger than the thickness of the first semiconductor layer SEL1, which is measured in the second direction D2 at the top level of the first recess RS1. The first semiconductor layer SEL1 may have a ‘U’-shaped section, due to a sectional profile of the first recess RS1.

The second semiconductor layer SEL2 may fill a remaining space of the first recess RS1 excluding the first semiconductor layer SEL1. In other words, the second semiconductor layer SEL2 may fill a space formed by the first semiconductor layer SEL1. A volume of the second semiconductor layer SEL2 may be larger than a volume of the first semiconductor layer SEL1. In other words, a ratio of the volume of the second semiconductor layer SEL2 to a total volume of the first source/drain pattern SD1 may be greater than a ratio of the volume of the first semiconductor layer SEL1 to the total volume of the first source/drain pattern SD1.

Each of the first and second semiconductor layers SEL1 and SEL2 may be formed of or include silicon-germanium (SiGe). For example, the first semiconductor layer SEL1 may have a relatively low germanium concentration. In another embodiment, the first semiconductor layer SEL1 may contain only silicon (Si) but not germanium (Ge). The germanium concentration of the first semiconductor layer SEL1 may range from 0 at % to 30 at %.

The second semiconductor layer SEL2 may have a relatively high germanium concentration. As an example, the germanium concentration of the second semiconductor layer SEL2 may range from 30 at % to 70 at %. The germanium concentration of the second semiconductor layer SEL2 may increase in the third direction D3. For example, the germanium concentration of the second semiconductor layer SEL2 may be about 40 at % near the first semiconductor layer SEL1 but may be about 60 at % at its top level.

The first and second semiconductor layers SEL1 and SEL2 may include impurities (e.g., boron), allowing the first source/drain pattern SD1 to have the p-type conductivity. In an embodiment, a concentration of impurities in the second semiconductor layer SEL2 (in at %) may be higher than that in the first semiconductor layer SEL1.

Gate electrodes GE may be provided to cross the first and second channel patterns CH1 and CH2 and to extend in the first direction D1. The gate electrodes GE may be arranged with a first pitch P1 in the second direction D2. Each of the gate electrodes GE may be vertically overlapped with the first and second channel patterns CH1 and CH2.

The gate electrode GE may include a first inner electrode PO1 interposed between the active pattern AP1 or AP2 and the first semiconductor pattern SP1, a second inner electrode PO2 interposed between the first semiconductor pattern SP1 and the second semiconductor pattern SP2, a third inner electrode PO3 interposed between the second semiconductor pattern SP2 and the third semiconductor pattern SP3, and an outer electrode PO4 on the third semiconductor pattern SP3.

Referring back to FIG. 17A, the first to third inner electrodes PO1, PO2, and PO3 of the gate electrode GE on the PMOSFET region PR may have different widths from each other in the second direction D2. For example, the largest width of the third inner electrode PO3 in the second direction D2 may be larger than the largest width of the second inner electrode PO2 in the second direction D2. The largest width of the first inner electrode PO1 in the second direction D2 may be larger than the largest width of the third inner electrode PO3 in the second direction D2.

Referring back to FIG. 17D, the gate electrode GE may be provided to face a top surface TS, a bottom surface BS, and opposite side surfaces SW of each of the first to third semiconductor patterns SP1, SP2, and SP3. For example, the gate electrode GE may surround each of the first to third semiconductor patterns SP1, SP2, and SP3. In other words, the transistor according to the present embodiment may be a three-dimensional field effect transistor (e.g., MBCFET or GAAFET) in which the gate electrode GE is provided to three-dimensionally surround the channel pattern.

Referring back to FIGS. 16 and 17A to 17D, a pair of gate spacers GS may be respectively disposed on opposite side surfaces of the outer electrode PO4 of the gate electrode GE. The gate spacers GS may be extended along the gate electrode GE and in the first direction D1. Top surfaces of the gate spacers GS may be higher than a top surface of the gate electrode GE. The top surfaces of the gate spacers GS may be coplanar with a top surface of a first interlayer insulating layer 110, which will be described below. The gate spacers GS may be formed of or include at least one of SiCN, SiCON, or SiN. In an embodiment, the gate spacers GS may have a multi-layered structure including at least two layers, each of which is made of SiCN, SiCON, or SiN.

A gate capping pattern GP may be provided on the gate electrode GE. The gate capping pattern GP may be extended along the gate electrode GE and in the first direction D1. The gate capping pattern GP may be formed of or include a material having an etch selectivity with respect to first and second interlayer insulating layers 110 and 120, which will be described below. For example, the gate capping pattern GP may be formed of or include at least one of SiON, SiCN, SiCON, or SiN.

A gate insulating layer GI may be interposed between the gate electrode GE and the first channel pattern CH1 and between the gate electrode GE and the second channel pattern CH2. The gate insulating layer GI may cover the top surface TS, the bottom surface BS, and the opposite side surfaces SW of each of the first to third semiconductor patterns SP1, SP2, and SP3. The gate insulating layer GI may cover the top surface of the device isolation layer ST below the gate electrode GE (e.g., see FIG. 17D). The gate insulating layer GI may also cover the top surface of the first and second active patterns AP1 and AP2 (e.g., see FIG. 17D).

In an embodiment, the gate insulating layer GI may include a silicon oxide layer, a silicon oxynitride layer, and/or a high-k dielectric layer. The high-k dielectric layer may be formed of or include at least one of high-k dielectric materials whose dielectric constants are higher than that of silicon oxide. For example, the high-k dielectric material may include at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, or lead zinc niobate.

In an embodiment, the gate electrode GE may include a first metal pattern and a second metal pattern on the first metal pattern. The first metal pattern may be provided on the gate insulating layer GI and may be adjacent to the first to third semiconductor patterns SP1, SP2, and SP3. The first metal pattern may include a work-function metal, which can be used to adjust a threshold voltage of the transistor. By adjusting a thickness and composition of the first metal pattern, it is possible to realize a transistor having a desired threshold voltage. For example, the first to third inner electrodes PO1, PO2, and PO3 of the gate electrode GE may be composed of the first metal pattern or the work-function metal.

The first metal pattern may include a metal nitride layer. For example, the first metal pattern may be formed of or include at least one metallic material, which is selected from the group consisting of titanium (Ti), tantalum (Ta), aluminum (Al), tungsten (W) and molybdenum (Mo), and nitrogen (N). In an embodiment, the first metal pattern may further include carbon (C). The first metal pattern may include a plurality of stacked work-function metal layers.

The second metal pattern may be formed of or include a metallic material whose resistance is lower than the first metal pattern. For example, the second metal pattern may be formed of or include at least one metallic material, which is selected from the group consisting of tungsten (W), aluminum (Al), titanium (Ti), and tantalum (Ta). In an embodiment, the outer electrode PO4 of the gate electrode GE may include the first metal pattern and the second metal pattern on the first metal pattern.

Referring back to FIG. 17B, inner spacers IP may be provided on the NMOSFET region NR. The inner spacers IP may be respectively interposed between the first to third inner electrodes PO1, PO2, and PO3 of the gate electrode GE and the second source/drain pattern SD2. The inner spacers IP may be in direct contact with the second source/drain pattern SD2. Each of the first to third inner electrodes PO1, PO2, and PO3 of the gate electrode GE may be spaced apart from the second source/drain pattern SD2 by the inner spacer IP.

A first interlayer insulating layer 110 may be provided on the substrate SUB. The first interlayer insulating layer 110 may cover the gate spacers GS and the first and second source/drain patterns SD1 and SD2. The first interlayer insulating layer 110 may have a top surface that is substantially coplanar with the top surface of the gate capping pattern GP and the top surface of the gate spacer GS. A second interlayer insulating layer 120 may be provided on the first interlayer insulating layer 110 to cover the gate capping pattern GP. In an embodiment, at least one of the first and second interlayer insulating layers 110 and 120 may include a silicon oxide layer.

A pair of dividing (or division) structures DB, which are opposite to each other in the second direction D2, may be provided at both sides of the logic cell LC. For example, the division structure DB may be provided on a border of the logic cell LC. The division structure DB may be extended in the first direction D1 to be parallel to the gate electrodes GE. A pitch between the dividing structure DB and the gate electrode GE, which are adjacent to each other, may be equal to the first pitch P1.

The division structure DB may penetrate the gate electrode GE and may be extended into the first and second active patterns AP1 and AP2. The division structure DB may penetrate the first and second channel patterns CH1 and CH2. The division structure DB may separate the PMOSFET and NMOSFET regions PR and NR of the logic cell LC from the PMOSFET and NMOSFET regions PR and NR of another logic cell adjacent thereto.

Active contacts AC may be provided to penetrate the first and second interlayer insulating layers 110 and 120 and may be electrically connected to the first and second source/drain patterns SD1 and SD2, respectively. A pair of the active contacts AC may be respectively provided at both sides of the gate electrode GE. When viewed in a plan view, the active contact AC may be a bar-shaped pattern elongated in the first direction D1.

The active contact AC may be a self-aligned contact. For example, the active contact AC may be formed by a self-alignment process using the gate capping pattern GP and the gate spacer GS. In an embodiment, the active contact AC may cover at least a portion of a side surface of the gate spacer GS. Furthermore, the active contact AC may cover a portion of the top surface of the gate capping pattern GP.

Silicide patterns SC may be respectively interposed between the active contact AC and the first source/drain pattern SD1 and between the active contact AC and the second source/drain pattern SD2. For example the silicide patterns SC may be in direct contact with the active contact AC and the first and second source/drain patterns SD1 and SD2. The active contact AC may be electrically connected to the source/drain pattern SD1 or SD2 through the silicide pattern SC. The silicide pattern SC may be formed of or include at least one of metal silicide materials (e.g., titanium silicide, tantalum silicide, tungsten silicide, nickel silicide, and cobalt silicide).

The active contact AC may include a conductive pattern FM and a barrier pattern BM enclosing the conductive pattern FM. For example, the conductive pattern FM may be formed of or include at least one metal of aluminum, copper, tungsten, molybdenum, or cobalt. The barrier pattern BM may be provided to cover side and bottom surfaces of the conductive pattern FM. In an embodiment, the barrier pattern BM may include a metal layer and a metal nitride layer. The metal layer may be formed of or include at least one of titanium, tantalum, tungsten, nickel, cobalt, or platinum. The metal nitride layer may be formed of or include at least one of titanium nitride (TiN), tantalum nitride (TaN), tungsten nitride (WN), nickel nitride (NiN), cobalt nitride (CON), or platinum nitride (PtN).

A first metal layer M1 may be provided in a third interlayer insulating layer 130. The first metal layer M1 may include first and second power lines MPR1 and MPR2, first, second, third, fourth and fifth lower interconnection lines MI1, MI2, MI3, MI4 and MI5, and lower vias VI1. The lower vias VI1 may be provided below the first and second power lines MPR1 and MPR2 and the first to fifth lower interconnection lines MI1 to MI5.

The first and second power lines MPR1 and MPR2 may be extended in the second direction D2 to cross the logic cell LC and to be parallel to each other. A drain voltage VDD and a source voltage VSS may be applied to the first and second power lines MPR1 and MPR2, respectively.

Referring to FIG. 16, a first cell boundary CB1, which is extended in the second direction D2, may be defined in the logic cell LC. A second cell boundary CB2, which is extended in the second direction D2, may be defined at an opposite side of the first cell boundary CB1. The first power line MPR1 applied with the drain voltage VDD may be disposed on the first cell boundary CB1. In other words, the first power line MPR1 applied with the drain voltage VDD may be extended along the first cell boundary CB1 or in the second direction D2. The second power line MPR2 applied with the source voltage VSS (e.g., a ground voltage) may be disposed on the second cell boundary CB2. In other words, the second power line MPR2 applied with the source voltage VSS may be extended along the second cell boundary CB2 or in the second direction D2.

The first to fifth lower interconnection lines MI1 to MI5 may be disposed between the first and second power lines MPR1 and MPR2. For example, first to fifth interconnection tracks MTR1 to MTR5 may be defined between the first and second power lines MPR1 and MPR2. The first to fifth interconnection tracks MTR1 to MTR5 may be arranged in sequence. The first to fifth interconnection tracks MTR1 to MTR5 may be extended in the second direction D2 to be parallel to each other. The first to fifth lower interconnection lines MI1 to MI5 may be arranged with a second pitch P2 in the first direction D1. The second pitch P2 may be smaller than the first pitch P1.

At least one of the first lower interconnection lines MI1 may be disposed on the first interconnection track MTR1, at least one of the second lower interconnection lines MI2 may be disposed on the second interconnection track MTR2, at least one of the third lower interconnection lines MI3 may be disposed on the third interconnection track MTR3, at least one of the fourth lower interconnection lines MI4 may be disposed on the fourth interconnection track MTR4, and at least one of the fifth lower interconnection lines MI5 may be disposed on the fifth interconnection track MTR5.

The first to fifth lower interconnection lines MI1 to MI5 may be extended along the first to fifth interconnection tracks MTR1-MTR5, respectively, or in the second direction D2 and may be parallel to each other. When viewed in a plan view, each of the first to fifth lower interconnection lines MI1 to MI5 may be a line- or bar-shaped pattern.

A linewidth of each of the first and second power lines MPR1 and MPR2 may be a first width W1. A linewidth of each of the first to fifth lower interconnection lines MI1 to MI5 may be a second width W2. The second width W2 may be smaller than the first width W1 (e.g., see FIG. 17C). For example, the second width W2 may be smaller than 12 nm. The first width W1 may be larger than 12 nm.

A gate contact GC may be provided to penetrate the third interlayer insulating layer 130, the second interlayer insulating layer 120, and the gate capping pattern GP and may be electrically connected to the gate electrode GE. The gate contact GC may electrically connect the gate electrode GE to one of the first to fifth lower interconnection lines MI1 to MI5. For example, the gate contact GC may electrically connect the gate electrode GE to the fourth lower interconnection line MI4, as shown in FIG. 17B. Additionally, an empty region on each of the active contacts AC adjacent to the gate contact GC may be filled with an upper insulating pattern UIP, as shown in FIG. 17B. Accordingly, it is possible to prevent a process failure (e.g., a short circuit), which may occur when the gate contact GC is in contact with the active contact AC adjacent thereto.

The lower vias VI1 may be interposed between the first and second power lines MPR1 and MPR2 and the active contacts AC. The lower vias VI1 may be interposed between the first to fifth lower interconnection lines MI1-MI5 and the active contacts AC.

The interconnection lines MPR1, MPR2, and MI1 to MI5 of the first metal layer M1 and the lower via VI1 thereunder may be formed by separate processes. In an embodiment, each of the interconnection lines MPR1, MPR2, and MI1 to MI5 and the lower via VI1 of the first metal layer M1 may be formed by a single damascene process.

The lower via VI1 and the gate contact GC may be formed (e.g., simultaneously) using the same process. The lower via VI1 and the gate contact GC may be formed of or include the same metallic material. For example, the lower via VI1 and the gate contact GC may be formed of or include at least one of metallic materials (e.g., copper (Cu), aluminum (Al), ruthenium (Ru), cobalt (Co), tungsten (W), and molybdenum (Mo)).

According to an embodiment of the inventive concept, the lower via VI1 and the gate contact GC may be formed by a method of forming an isolated pattern using the EUV lithography process previously described with reference to FIGS. 8A to 9B. In other words, the third interlayer insulating layer 130 may be used as the etch target layer TGL of FIGS. 9A and 9B, and the lower via VI1 and the gate contact GC may be formed by forming a hole in the etch target layer TGL using the afore-described EUV lithography process and filling the hole with a metallic material.

A second metal layer M2 may be provided in a fourth interlayer insulating layer 140. The second metal layer M2 may include upper interconnection lines M2_I. Each of the upper interconnection lines M2_I may be a line- or bar-shaped pattern extending in the first direction D1. In other words, the upper interconnection lines M2_I may be extended in the first direction D1 to be parallel to each other.

The second metal layer M2 may further include upper vias VI2. The upper vias VI2 may be provided below the upper interconnection lines M2_I. The upper vias VI2 may be respectively interposed between the interconnection lines MPR1, MPR2, and MI1 to MI5 of the first metal layer M1 and the upper interconnection lines M2_I. In an embodiment, the upper via VI2 may also be formed by the afore-described method of forming an isolated pattern using the EUV lithography process of FIGS. 8A to 9B.

In an embodiment, additional metal layers (e.g., M3, M4, M5, and so forth) may be further stacked on the fourth interlayer insulating layer 140. Each of the stacked metal layers may include routing lines.

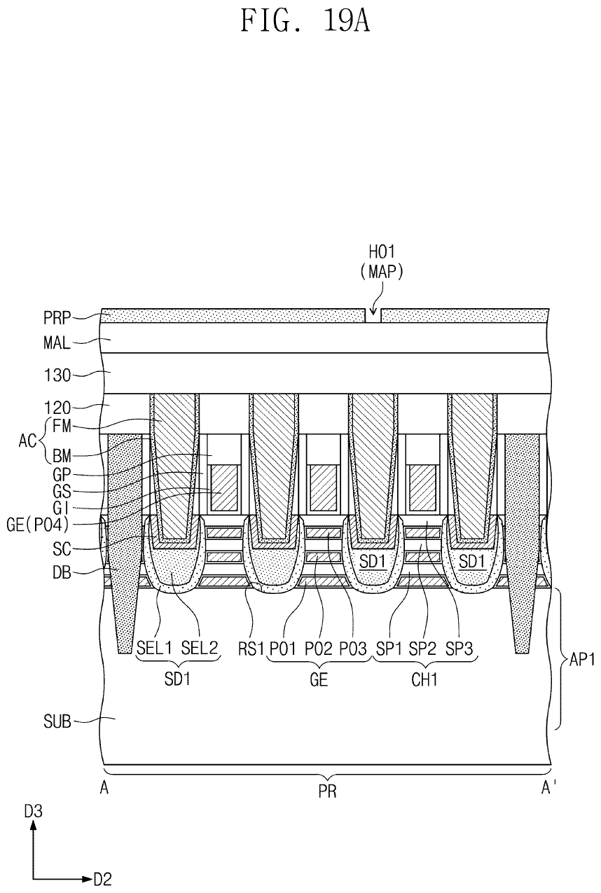

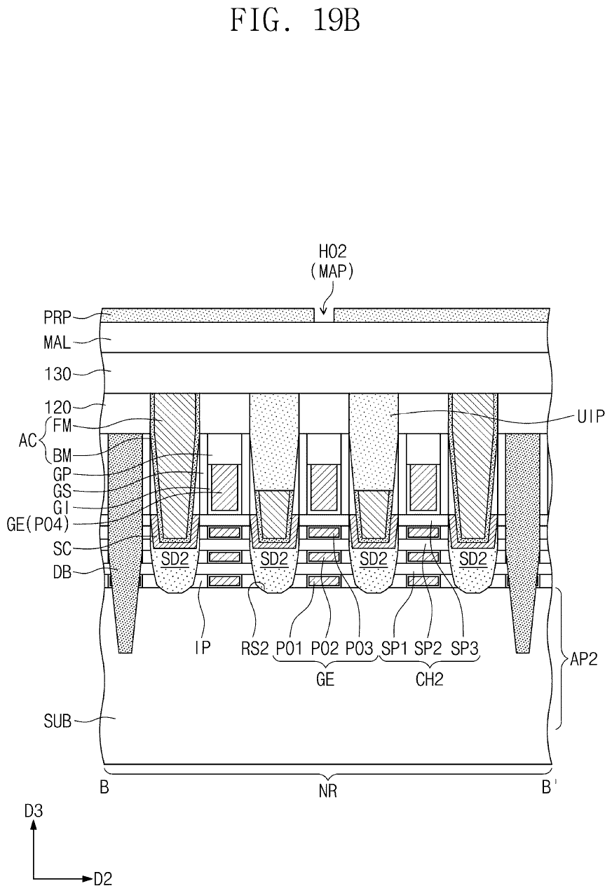

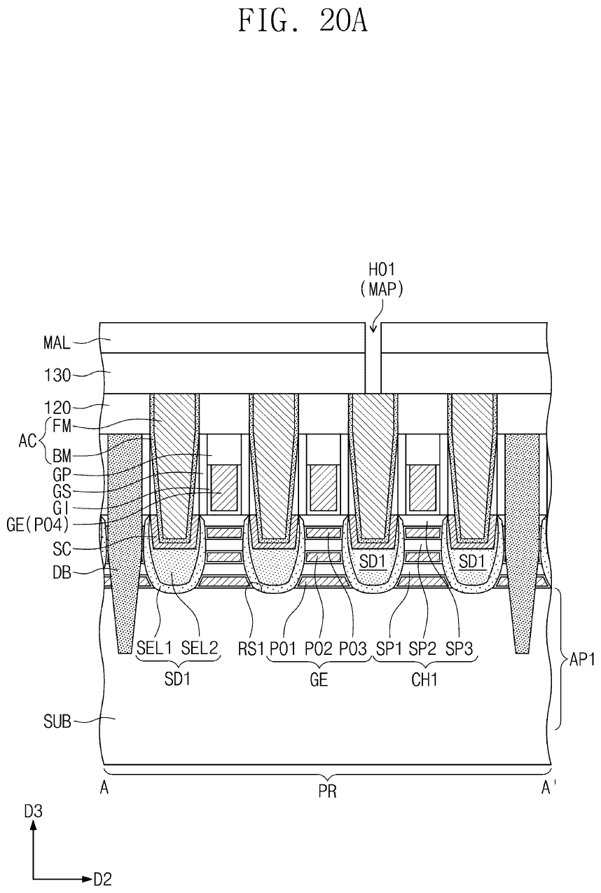

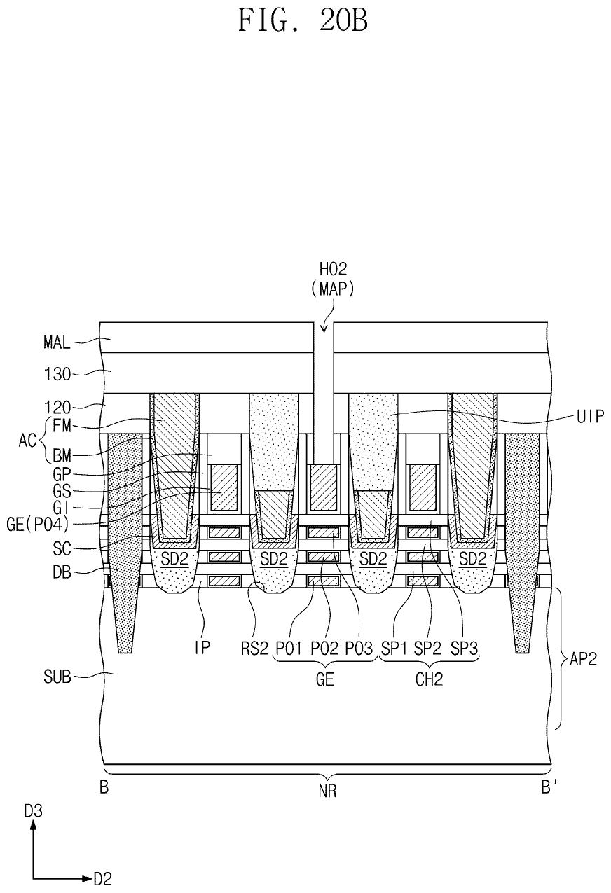

FIG. 18 is a plan view illustrating a reflective mask according to an embodiment of the inventive concept. FIGS. 19A, 19B, 20A, and 20B are sectional views illustrating a method of fabricating a semiconductor device according to an embodiment of the inventive concept. More specifically, FIGS. 19A, 19B, 20A, and 20B are sectional views illustrating a method of forming the gate contact and the lower via. FIGS. 19A and 20A are sectional views corresponding to the line A-A′ of FIG. 16. FIGS. 19B and 20B are sectional views corresponding to the line B-B′ of FIG. 16.

Referring to FIG. 18, the reflective mask MA may be an EUV mask, which is used to form the gate contact GC and the lower via VI1 previously described with reference to FIGS. 16 and 17A to 17D. The reflective mask MA may include the main patterns MAP defining the gate contact GC and the lower via VI1. Each of the main patterns MAP may be an isolated pattern. The non-diffraction patterns NDP described above may be provided around each of the main patterns MAP. A pitch between the non-diffraction patterns NDP may be determined to be less than the diffraction limit.

Referring to FIGS. 19A and 19B, a front-end-of-line (FEOL) layer may be formed on the substrate SUB. The FEOL layer may include the logic transistors previously described with reference to FIG. 16 and FIGS. 17A to 17D. The third interlayer insulating layer 130 may be formed on the FEOL layer. The mask layer MAL and a photoresist layer may be sequentially formed on the third interlayer insulating layer 130.

An EUV exposure process may be performed on the photoresist layer, using the reflective mask MA described with reference to FIG. 18. The photoresist layer may be developed to form the photoresist pattern PRP. For example, the photoresist pattern PRP may include a first hole HO1 and a second hole HO2. The first hole HO1 may define the lower via VI1, and the second hole HO2 may define the gate contact GC. The first hole HO1 may vertically overlap the active contact AC, and the second hole HO2 may vertically overlap the gate electrode GE.

Referring to FIGS. 20A and 20B, the first hole HO1 and the second hole HO2 may be formed in the mask layer MAL by patterning the mask layer MAL using the photoresist pattern PRP as an etch mask. The third interlayer insulating layer 130 may be anisotropically etched using the mask layer MAL as an etch mask. In other words, the first and second holes HO1 and HO2 may penetrate the third interlayer insulating layer 130. For the second hole HO2, the anisotropic etching process may be performed on the second interlayer insulating layer 120 and the gate capping pattern GP. The first hole HO1 may be formed to expose a top surface of the active contact AC, and the second hole HO2 may be formed to expose a top surface of the gate electrode GE.

Referring back to FIGS. 16 and 17A to 17D, the mask layer MAL may be selectively removed. The lower via VI1 and the gate contact GC may be respectively formed by filling the first hole HO1 and the second hole HO2 with a metallic material. The first metal layer M1 may be formed on the lower via VI1 and the gate contact GC. The second metal layer M2 may be formed on the first metal layer M1. The upper via VI2 may also be formed using the EUV lithography process described above.

According to an embodiment of the inventive concept, it is possible to improve reliability in an EUV lithography process to form an isolated pattern (e.g., a via pattern and a gate contact), even when an annular illumination is used as an EUV light source. As a result, it is possible to improve the reliability of the semiconductor device.

According to an embodiment of the inventive concept, an EUV reflective mask may be used to stably perform a printing process for an isolated pattern, even when an annular illumination is used. Thus, it is possible to maximize an SRAF effect and improve reliability of an EUV lithography process.

According to an embodiment of the inventive concept, the EUV reflective mask may be effectively used in a process of forming via patterns and/or contact patterns constituting a back-end-of-line (BEOL) layer. Thus, it is possible to increase an integration density of the semiconductor device and improve the reliability of the semiconductor device.

While example embodiments of the inventive concept have been particularly shown and described, it will be understood by one of ordinary skill in the art that variations in form and detail may be made thereto without departing from the spirit and scope of the inventive concept as set forth in the attached claims.

What is claimed is:

1. An extreme ultraviolet (EUV) reflective mask, comprising:
a mask substrate, a reflection layer on the mask substrate, and an absorption layer on the reflection layer,
wherein the absorption layer comprises a main pattern and non-diffraction patterns near the main pattern,
the non-diffraction patterns form a honeycomb shape,
a pitch between the non-diffraction patterns is less than a diffraction limit, and
the main pattern is isolated from the non-diffraction patterns.

2. The EUV reflective mask of claim 1, wherein the non-diffraction patterns prevent diffraction of EUV reflection light.

3. The EUV reflective mask of claim 1, wherein an EUV light source, which is used for the EUV reflective mask, is an annular illumination.

4. The EUV reflective mask of claim 3, wherein an outer radius or sigma outer of the annular illumination ranges from 0.7 to 0.9.

5. The EUV reflective mask of claim 1, wherein the pitch between the non-diffraction patterns is less than 22.7 nm.

6. The EUV reflective mask of claim 1, wherein an intensity of EUV reflection light by the non-diffraction patterns has a flat profile.

7. The EUV reflective mask of claim 6, wherein the intensity of the EUV reflection light by the non-diffraction patterns is smaller than a threshold value.

8. The EUV reflective mask of claim 1, wherein the main pattern is printed in a photoresist layer and the non-diffraction patterns are not printed in the photoresist layer.

9. The EUV reflective mask of claim 1, wherein the non-diffraction patterns, which are arranged in a first direction, form a first column and a second column,
the first column and the second column are adjacent to each other in a second direction, and
the second column is offset from the first column in the first direction.

10. The EUV reflective mask of claim 1, wherein the absorption layer contains a ruthenium alloy or a tantalum alloy, and
the reflective mask is an EUV phase shift mask.

11. A method of fabricating a semiconductor device, comprising:
forming an etch target layer, a mask layer, and a photoresist layer sequentially stacked on a substrate;
performing a printing process using an extreme ultraviolet (EUV) reflective mask on the photoresist layer to form a photoresist pattern including a hole; and
patterning the mask layer and the etch target layer using the photoresist pattern as an etch mask,
wherein the EUV reflective mask comprises a main pattern and non-diffraction patterns,
the non-diffraction patterns form a honeycomb shape,
a pitch between the non-diffraction patterns is less than a diffraction limit, and
the hole is printed from the main pattern.

12. The method of claim 11, wherein the hole is an isolated pattern.

13. The method of claim 11, further comprising filling the hole, which is formed in the etch target layer, with a metallic material.

14. The method of claim 13, wherein the metallic material filling the hole forms a via pattern or a contact pattern.

15. The method of claim 11, wherein the non-diffraction patterns are not printed in the photoresist layer.

16. A method of fabricating a semiconductor device, comprising:
forming a front-end-of-line (FEOL) layer on a substrate, the FEOL layer comprising a plurality of transistors on the substrate;
forming an interlayer insulating layer on the FEOL layer;
forming a mask layer and a photoresist layer on the interlayer insulating layer;
performing a printing process using an extreme ultraviolet (EUV) reflective mask on the photoresist layer to form a photoresist pattern including a hole;
patterning the mask layer and the interlayer insulating layer using the photoresist pattern as an etch mask; and
forming a via pattern or a contact pattern by filling the hole, which is in the interlayer insulating layer, with a metallic material,
wherein the EUV reflective mask comprises an isolated pattern and non-diffraction patterns near the isolated pattern,
a pitch between adjacent ones of the non-diffraction patterns is less than a diffraction limit, and
the hole is printed from the isolated pattern.

17. The method of claim 16, wherein the non-diffraction patterns, which are arranged in a first direction, form a first column and a second column,
the first column and the second column are adjacent to each other in a second direction, and
the second column is offset from the first column in the first direction.

18. The method of claim 16, further comprising forming a back-end-of-line (BEOL) layer on the interlayer insulating layer,
wherein the via or contact pattern electrically connects the FEOL and BEOL layers to each other.

19. The method of claim 16, wherein an extreme ultraviolet (EUV) light source, which is used for the EUV reflective mask, is an annular illumination.

20. The method of claim 16, wherein the non-diffraction patterns are not printed in the photoresist layer.
